(19) United States
(12) Patent Application Publication
(10) Pub. No.: US 2013/0170170 A1
(43) Pub. Date: Jul. 4, 2013

(54) COUNTER MACHINE WITH DISPLAY

(71) Applicants: LIANG-CHIN WANG, Tu-Cheng (TW); GANG SU, Wuhan City (CN); LING-XIN ZENG, Wuhan City (CN); YAN-YAN XIAO, Wuhan City (CN)

(72) Inventors: LIANG-CHIN WANG, Tu-Cheng (TW); GANG SU, Wuhan City (CN); LING-XIN ZENG, Wuhan City (CN); YAN-YAN XIAO, Wuhan City (CN)

(21) Appl. No.: 13/666,046

(22) Filed: Nov. 1, 2012

(30) Foreign Application Priority Data
Dec. 29, 2011 (CN) 201110450568.X

(51) Int. Cl. H05K 7/02

(52) U.S. Cl. 361/807

(57) ABSTRACT

A counter machine includes a display, a first connecting member, a support, and a second connecting member. The first connecting member is secured to the display and includes a first block. The second connecting member is engaged with the first connecting member and includes a second block. The first connecting member is rotatable relative to the second connecting member. When the first block is blocked by the second block, the first connecting member is blocked from rotating relative to the second connecting member.

### BACKGROUND

1. Technical Field

The present disclosure relates to counter machines, more particularly to a data center with a display.

2. Description of Related Art

A banknote counter machine is widely used to count banknotes. A display is usually integrated on the banknote counter machine to shows the number of the banknotes. However, the display cannot be rotated relative to a main body of the banknote counter machine.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of a counter machine in accordance with an embodiment.

FIG. 2 is similar to FIG. 1, but viewed in a different aspect.

FIG. 3 is an assembled, cutaway view of the counter machine of FIG. 1.

FIG. 4 is similar to FIG. 3, but viewed from a different aspect.

FIG. 5 is a cross-sectional, cutaway view of the counter machine of FIG. 3 taken along a line V-V.

FIG. 6 is a cross-sectional, cutaway view of the counter machine of FIG. 3, taken along a line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

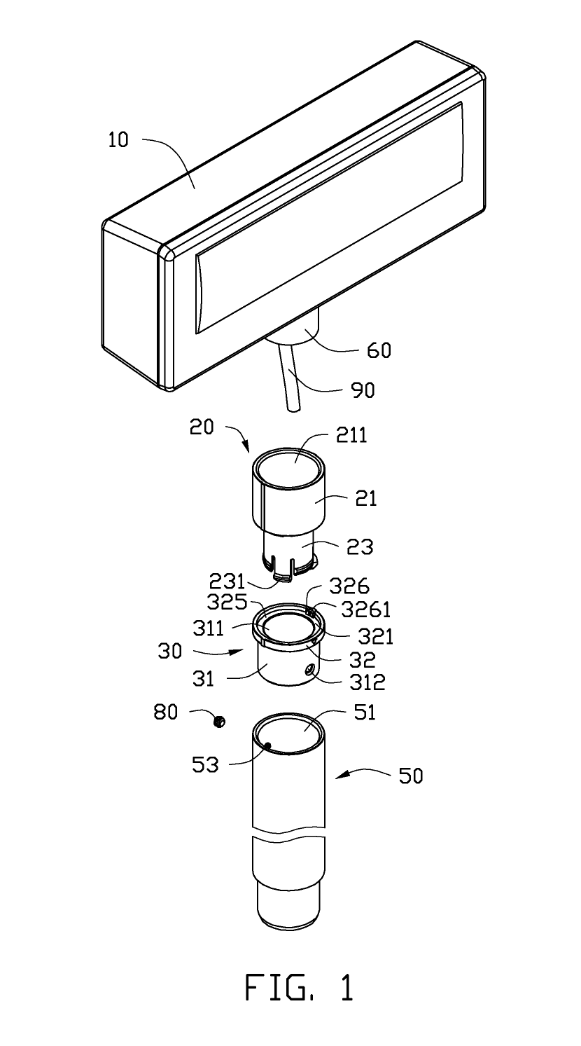

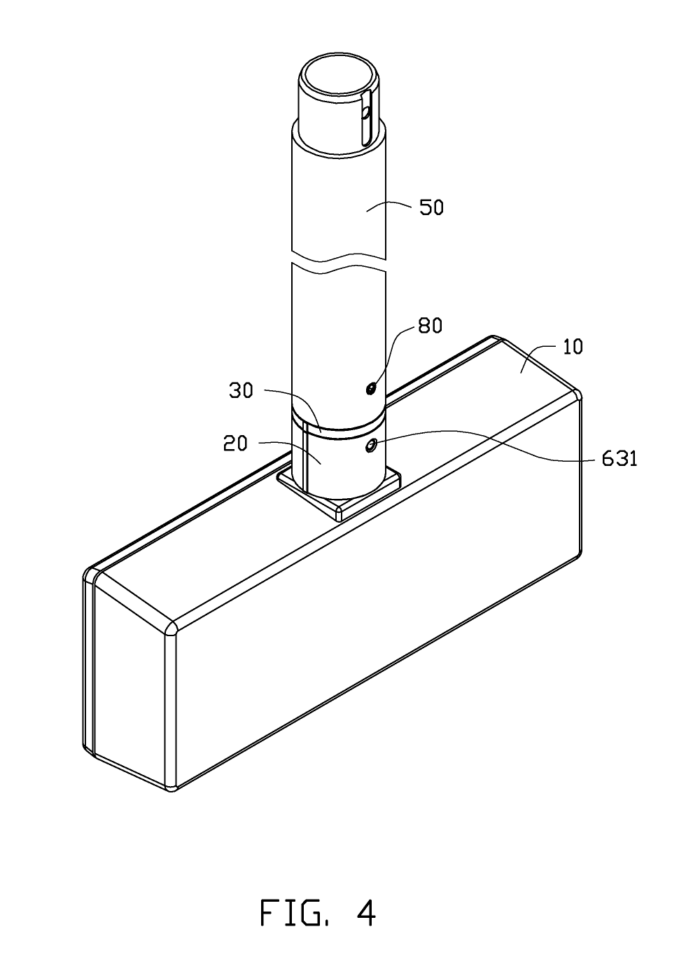

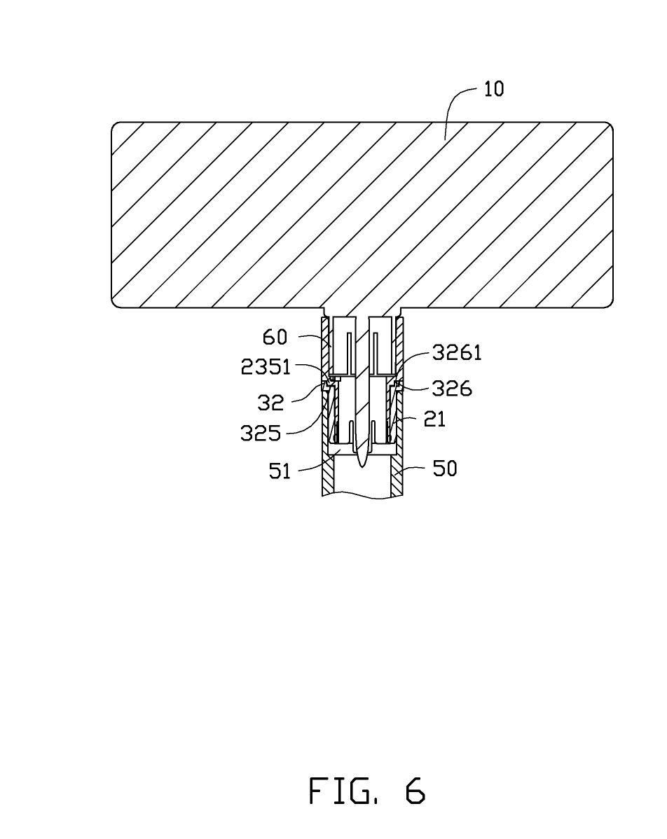

FIGS. 1-6 illustrate a counter machine of an embodiment. The counter machine may be, for example, a banknote counter machine.

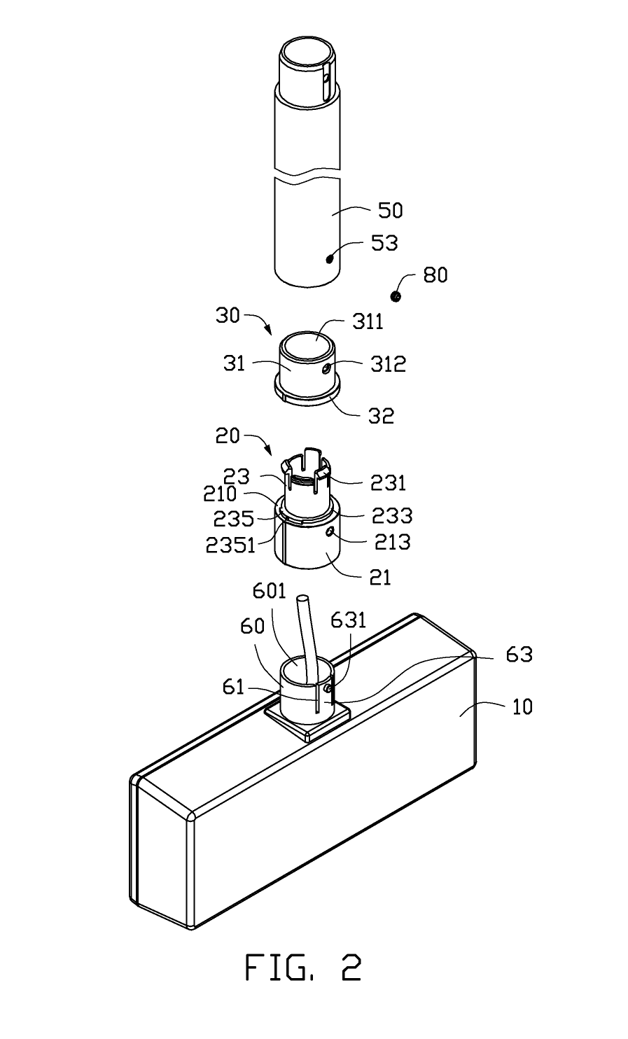

The counter machine comprises a display 10, a first connecting member 20, a second connecting member 30, and a support 50. The first connecting member 20 is secured to the display 10 and comprises a first block 235 (see FIG. 2). The second connecting member 30 is engaged with the first connecting member 20 and comprises a second block 326 (see FIG. 1). The first connecting member 20 is rotatable relative to the second connecting member 30. When the first block 235 is engaged with the second block 326, the first connecting member 20 is blocked from rotating relative to the second connecting member 30. In an embodiment, the support is secured to a main body (not shown) of the counter machine.

The first connecting member 20 comprises a plurality of resilient hooks 231, and the plurality of resilient hooks 231 are engaged with the second connecting member 30 to prevent the second connecting member 30 from disengaging from the first connecting member 10. In an embodiment, the number of the plurality of resilient hooks 231 is three, and the three resilient hooks 231 are arranged evenly at an edge of the first connecting member 20.

The first connecting member 20 further comprises a blocking surface 210 (see FIG. 2), and the second connecting member 30 is located between the resilient hook 231 and the blocking surface 210.

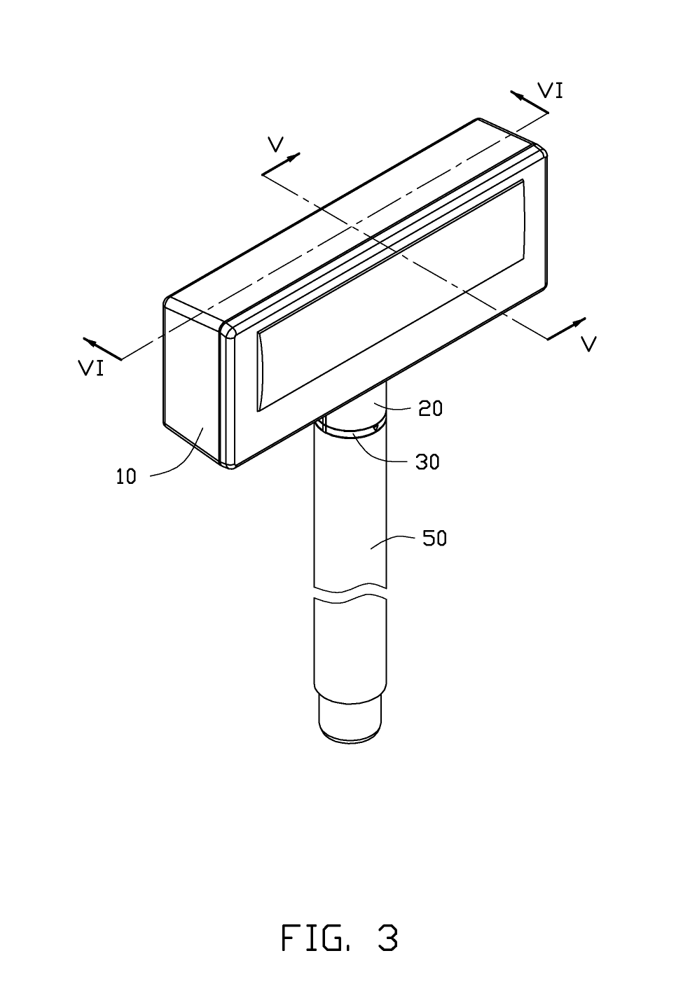

The second connecting member 30 defines a pivot hole 311. The first connecting member 20 is received in the pivot hole 311. The resilient hook 231 extends through the pivot hole 311 to engage with the second connecting member 30. When the first connecting member 20 is assembled to the second connecting member 30, the plurality of resilient hooks 231 are resiliently deformed so that the first connecting member 20 can be inserted into the pivot hole 311. When the plurality of resilient hooks 231 extend out of the pivot hole 311, the plurality of resilient hooks 231 return and engaged with the second connecting member 30 (see FIGS. 3-6).

The first connecting member 20 further comprises a first protrusion 2351. The second member 30 comprises friction portion 233. The first protrusion 2351 abuts against the friction portion 233 to provide resistance between the first connecting member 20 and the second connecting member 30. The protrusion 2351 is located on the first block 235. Therefore, when the first connecting member 20 is rotated relative to the second connecting member 30, the first connecting member 20 can be stopped at any position relative to the second connecting member 30.

The second connecting member 30 comprises a second protrusion 3261. The second protrusion 3261 abuts against the first connecting member 20 to provide resistance between the first connecting member 20 and the second connecting member 30. Therefore, due to engagement between the first protrusion 2351 and friction portion 233 and between the second protrusion 3261 and the first connecting member 20, the first connecting member 20 can be stopped at any position relative to the second connecting member 30 when the first connecting member 20 is rotated relative to the second connecting member 30.

The display 10 comprises a mounting portion 60. The mounting portion 60 comprises a pin 631. The first connecting member 20 defines a securing hole 213. The pin 631 is received in the securing hole 213 to prevent the display 10 from rotating relative to the first connecting member 20.

The mounting portion 60 of the display 10 defines a receiving hole 601. The first connecting member 20 defines a through hole 211. The support 50 defines an installing hole 51. The mounting portion 60 is received in the through hole 211, the first connecting member 20 is received in the pivot hole 311, and the second connecting member 30 is received in the installing hole 51. A cable 90 extends through the receiving hole 601, the through hole 211, the pivot hole 311, and the installing hole 51. The cable 90 can be connected to a main body of the counter machine to provide power and/or voltage signal to the display 10.

The mounting portion 60 comprises a resilient piece 63. Two gaps 631 are defined in the mounting portion 60 at two opposite sides of the resilient piece 63so that the resilient piece 63 can be deformed easily. The pin 631 extends from the resilient piece 631. When the mounting portion 60 is assembled to the first connecting member 20, the resilient piece 631 is resiliently deformed to enable the mounting portion 60 inserted in the through hole 211 of the first connecting member 20. The mounting portion 60 is slid in the through hole 211, and when the pin 631 is aligned with the securing hole 213, the resilient piece 63 rebounds to insert the pin 631 in the securing hole 213 (see FIGS. 3-6).

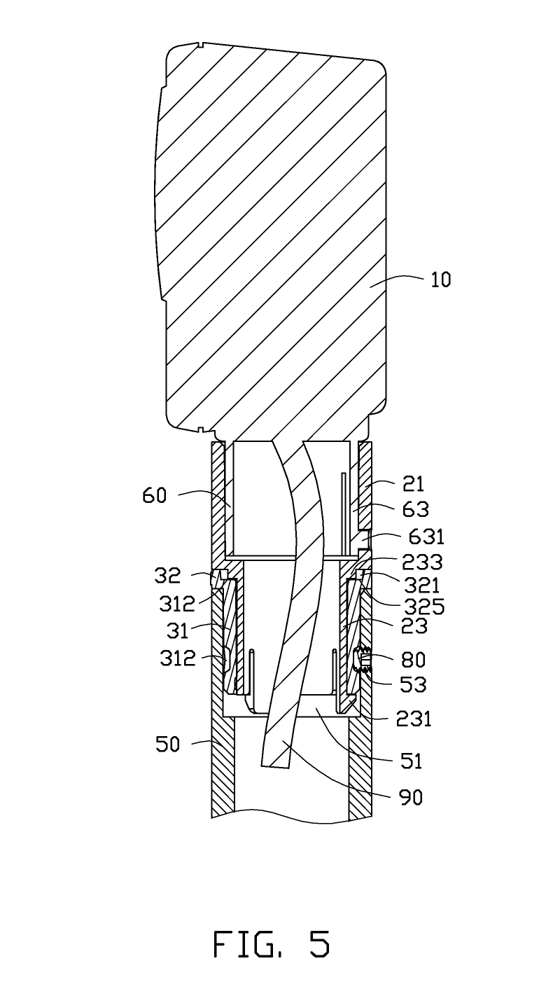

The second connecting member 30 defines a mounting hole 312. The support 50 defines a fixing hole 53. A fastener 80, such as a screw, is fixed in the fixing hole 53 and the mounting hole 312 to secure the second connecting member 30 to the support 50 (see FIG. 5). Therefore, the second connecting member 30 cannot be rotated relative to the support 50.

In an embodiment, the first connecting member 20 comprises a base portion 21 and a connecting portion 23 extends from the base portion 21 (see FIGS. 1 and 2). The mounting portion 60 is received in the base portion 21. The connecting portion 23 is received in the pivot hole 311 of the second connecting member 30. The blocking surface 210 is an end surface connected to the connecting portion 23. The friction portion 233 is located on and surrounds the connecting portion 23. The first block 235 extends from the friction portion 233. The second connecting member 30 comprises a main body 31 and a supporting portion 32 extends from main body 31 (see FIGS. 1 and 2). The main body 31 is received in the receiving hole 51 of the support 50. The supporting portion 32 is supported on the support 50. The supporting portion 32 comprises a supporting surface 325 connected to the main body 31, and the blocking surface 210 abuts the supporting surface 235.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A counter machine comprising:
a display;
a first connecting member secured to the display, the first connecting member comprising a first block;
a support; and
a second connecting member engaged with the first connecting member, the second connecting member comprising a second block;
wherein the first connecting member is rotatable relative to the second connecting member, and when the first block is blocked by the second block, the first connecting member is blocked from rotating relative to the second connecting member.

2. The counter machine of claim 1, wherein the first connecting member comprise a resilient hook, and the resilient hook is engaged with the second connecting member to prevent the second connecting member from disengaging from the first connecting member.

3. The counter machine of claim 2, wherein the first connecting member further comprises a blocking surface, and the second connecting member is located between the resilient hook and the blocking surface.

4. The counter machine of claim 2, wherein the second connecting member defines a pivot hole, the first connecting member is received in the pivot hole, and the resilient hook extends through the pivot hole to engage with the second connecting member.

5. The counter machine of claim 1, wherein the first connecting member further comprises a first protrusion, and the second member comprises friction portion, and the first protrusion abuts against the friction portion to provide a resistance force between the first connecting member and the second connecting member.

6. The counter machine of claim 5, wherein the first protrusion is located on the first block.

7. The counter machine of claim 1, wherein the second connecting member comprises a second protrusion, and the second protrusion abuts against the first connecting member to provide a resistance force between the first connecting member and the second connecting member.

8. The counter machine of claim 1, wherein the display comprises a mounting portion, the mounting portion comprises a pin, and the first connecting member defines a securing hole, and the pin is received in the securing hole to prevent the display from rotating relative to the first connecting member.

9. The counter machine of claim 8, wherein the mounting portion defines a receiving hole, the first connecting member defines a through hole, the second connecting member defines a pivot hole, the support defines an installing hole, the mounting portion is received in the through hole, the first connecting member is received in the pivot hole, the second connecting member is received in the installing hole, and a cable extends through the receiving hole, the through hole, the pivot hole, and the installing hole.

10. The counter machine of claim 8, wherein the mounting portion comprises a resilient piece and defines a gap at two opposite sides of the resilient piece for deforming the resilient piece, and the pin is located on the resilient piece.

11. The counter machine of claim 1, wherein the second connecting member defines a mounting hole, the support defines a fixing hole, and a fastener is fixed in the fixing hole and the mounting hole to secure the second connecting member to the support.

12. A counter machine comprising:
a display;
a first connecting member secured to the display, the first connecting member comprising a first block and a resilient hook; and
a second connecting member rotatably engaged with the first connecting member by the resilient hook, the second connecting member comprising a second block;
wherein when the first block is blocked by the second block, the first connecting member is blocked from rotating relative to the second connecting member.

13. The counter machine of claim 12, wherein the first connecting member further comprises a blocking surface, and the second connecting member is located between the resilient hook and the blocking surface.

14. The counter machine of claim 12, wherein the second connecting member defines a pivot hole, the first connecting member is received in the pivot hole, and the resilient hook extends through the pivot hole to engage with the second connecting member.

15. The counter machine of claim 12, wherein the first connecting member further comprises a first protrusion, and the second member comprises friction portion, and the first protrusion abuts against the friction portion to provide a resistance force between the first connecting member and the second connecting member.

16. The counter machine of claim 15, wherein the first protrusion is located on the first block.

17. The counter machine of claim 12, wherein the second connecting member comprise second protrusion, and the second protrusion abuts against the first connecting member to provide a resistance force between the first connecting member and the second connecting member.

18. The counter machine of claim 12, wherein the display comprises a mounting portion, the mounting portion comprises a resilient piece with a pin, the first connecting member defines a securing hole, and the pin is received in the securing hole to prevent the display from rotating relative to the first connecting member.

19. The counter machine of claim 18, further comprising a support, wherein the mounting portion defines a receiving hole, the first connecting member defines a through hole, the second connecting member defines a pivot hole, the support defines an installing hole, the mounting portion is received in the through hole, the first connecting member is received in the pivot hole, the second connecting member is received in the installing hole, and a cable is extends through the receiving hole, the through hole, the pivot hole, and the installing hole.

20. The counter machine of claim 19, wherein the second connecting member defines a mounting hole, the support defines a fixing hole, and a fastener is fixed in the fixing hole and the mounting hole to secure the second connecting member to the support.
